(19) United States
(12) Patent Application Publication
(10) Pub. No.: US 2025/0351653 A1
(43) Pub. Date: Nov. 13, 2025

(54) ELECTRONIC APPARATUS AND METHOD FOR MANUFACTURING THE SAME

(71) Applicant: Samsung Display Co., LTD., Yongin-si (KR)

(72) Inventors: HYUNKYUNG YUN, Yongin-si (KR); HOIKWAN LEE, Yongin-si (KR)

(21) Appl. No.: 19/084,369

(22) Filed: Mar. 19, 2025

(30) Foreign Application Priority Data
May 8, 2024 (KR) 10-2024-0060425

(51) Int. Cl. H10H 29/855; H10H 29/01; H10H 29/80

(52) U.S. Cl. CPC H10H 29/8552; H10H 29/034; H10H 29/0363; H10H 29/842

(57) ABSTRACT

An electronic apparatus includes a display panel, and a window member disposed on the display panel. The window member may include a support film, a coating window disposed on the support film, and a light-blocking pattern spaced apart from the coating window with the support film disposed therebetween. The light-blocking pattern may be formed of a light-blocking composition including a black colorant, an ultraviolet photoinitiator, a near-infrared photosensitizer, a near-infrared photoinitiator, and an adhesive resin.

This application claims priority to Korean Patent Application No. 10-2024-0060425, filed on May 8, 2024, and all the benefits accruing therefrom under 35 U.S.C. § 119, the content of which in its entirety is herein incorporated by reference.

### BACKGROUND

### 1. Field

The invention herein relates to an electronic apparatus, and more particularly to an electronic apparatus including a coating window and a method for manufacturing the electronic apparatus.

### 2. Description of Related Art

Various electronic apparatuses used for multimedia devices, such as a television, a mobile phone, a tablet computer, and a game console are being developed. An electronic apparatus may include a display panel for generating images and videos, a window member for protecting the display panel, and a housing in which the display panel is accommodated. The window member and the housing may be coupled to constitute the exterior of the electronic apparatus, and when the window member is coupled to the housing, an adhesive may be used. An adhesive cured at a high temperature damages components of an electronic apparatus.

### SUMMARY

The invention provides an electronic apparatus having a reduced thickness and improved surface quality, while exhibiting excellent display quality.

The invention also provides an electronic apparatus manufacturing method exhibiting excellent processability and manufacturing efficiency.

An embodiment of the invention provides an electronic apparatus including a display panel and a window member disposed on the display panel, and including a support film, a coating window disposed on the support film, and a light-blocking pattern spaced apart from the coating window with the support film disposed therebetween, wherein the light-blocking pattern is formed of a light-blocking composition including a black colorant, an ultraviolet photoinitiator, a near-infrared photosensitizer, a near-infrared photoinitiator, and an adhesive resin.

In an embodiment, a first edge of the coating window, a second edge of the support film, and a third edge of the light-blocking pattern may be directed parallel to each other in a thickness direction.

In an embodiment, the electronic apparatus may further include a light control layer disposed between the display panel and the window member and an optical adhesive layer disposed between the light control layer and the window member, wherein a side surface of the light-blocking pattern may be in contact with the optical adhesive layer.

In an embodiment, the optical adhesive layer may cover a stepped portion defined by the side surface of the light-blocking pattern and a lower surface of the support film.

In an embodiment, the optical adhesive layer may have a thickness of about 100 μm to about 200 μm.

In an embodiment, the light-blocking pattern may have an optical density (OD) of about 3 or more, and an adhesive force of about 5B or more with respect to the support film, as measured in accordance with an ASTM D3359 method.

In an embodiment, the light-blocking pattern may have a thickness range of about 3 μm to about 50 μm.

In an embodiment, the electronic apparatus may further include a housing in which the display panel is accommodated, wherein an upper surface of the light-blocking pattern is in contact with the support film, and a lower surface of the light-blocking pattern is in contact with the housing.

In an embodiment, the support film entirely may overlap the coating window.

In an embodiment, the coating window may have a pencil hardness of about 9H or more, a bright spot occurrence height of about 11 cm or more, as evaluated with a Dupont impact tester, and an indentation modulus (EIT) of about 800 MPa or more, as measured with a Nano indenter.

In an embodiment, the coating window may have a transmittance of about 90% or more with respect to light having a visible light wavelength range, and a yellow index of about 1 or less.

In an embodiment, the support film and the coating window may each have a transmittance of about 50% or more with respect to light having a wavelength range of about 700 nm to about 1000 nm.

In an embodiment, the coating window may have a thickness range of about 300 μm to about 800 μm, and the support film may have a thickness range of about 100 μm to about 200 μm.

In an embodiment, the ultraviolet photoinitiator may include an iodonium salt, the near-infrared photosensitizer may include a heptamethine cyanine dye, the near-infrared photoinitiator may include a coumarinacyl anilinium salt (CAA salt), and the adhesive resin may include at least one of a silicone-based resin, a urethane-based resin, or an acryl-based resin.

In an embodiment, a method for manufacturing an electronic apparatus includes preparing a preliminary window member including a support film, a coating window disposed on the support film, and a preliminary light-blocking pattern spaced apart from the coating window with the support film disposed therebetween, accommodating a display panel in a housing, and providing the preliminary window member on the display panel and forming a window member by irradiating the preliminary light-blocking pattern with near-infrared rays, wherein the preparing of the preliminary window member includes preparing the support film, forming the preliminary light-blocking pattern by providing a light-blocking composition on one surface of the support film, and irradiating the light-blocking composition with ultraviolet rays and forming a coating window by providing coating liquid on the other surface of the support film which is spaced apart from the one surface in the thickness direction, wherein the light-blocking composition includes a black colorant, an ultraviolet photoinitiator, a near-infrared photosensitizer, a near-infrared photoinitiator, and an adhesive resin.

In an embodiment, in the forming of the window member, the near-infrared rays may pass through the support film and the coating window to be irradiated to the preliminary light-blocking pattern.

In an embodiment, the forming of the window member may be performed at a temperature of about 80° C. or less.

In an embodiment, in the forming of the preliminary light-blocking pattern, a total amount of the ultraviolet rays provided may be about 100 mJ or less.

In an embodiment, the ultraviolet photoinitiator may include an iodonium salt, the near-infrared photosensitizer may include a heptamethine cyanine dye, the near-infrared photoinitiator may include a coumarinacyl anilinium salt (CAA salt), and the adhesive resin may include at least one of a silicone-based resin, a urethane-based resin, or an acryl-based resin.

In an embodiment, the light-blocking composition may be provided through an inkjet printing method or a dispensing method.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view illustrating an electronic apparatus, according to an embodiment;

FIG. 2A is an exploded perspective view illustrating the electronic apparatus, according to an embodiment;

FIG. 2B is an exploded perspective view illustrating the electronic apparatus, according to an embodiment;

FIG. 3 is a cross-sectional view illustrating a portion taken along line I-I′ of FIG. 2B, according to an embodiment;

FIG. 4 is an enlarged cross-sectional view illustrating region AA′ of FIG. 3, according to an embodiment;

FIG. 5 is a cross-sectional view illustrating a portion taken along line II-II′ of FIG. 2B, according to an embodiment;

FIG. 6A is a flowchart illustrating an electronic apparatus manufacturing method, according to an embodiment;

FIG. 6B is a flowchart illustrating an electronic apparatus manufacturing method, according to an embodiment;

FIG. 7 is a view schematically illustrating an electronic apparatus manufacturing step, according to an embodiment;

FIG. 8 is a view schematically illustrating an electronic apparatus manufacturing step, according to an embodiment;

FIG. 9 is a view schematically illustrating an electronic apparatus manufacturing step, according to an embodiment; and

FIG. 10 is a view schematically illustrating an electronic apparatus manufacturing step, according to an embodiment.

### DETAILED DESCRIPTION

The invention may be implemented in various modifications and have various forms, and specific embodiments are illustrated in the drawings and described in detail in the text. It is to be understood, however, that the invention is not intended to be limited to the particular forms disclosed, but is intended to cover all modifications, equivalents, and alternatives falling within the spirit and scope of the invention.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. Also, in the drawings, the thicknesses, the ratios, and the dimensions of the elements are exaggerated for effective description of the technical contents. The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the invention. The singular forms include the plural forms as well, unless the context clearly indicates otherwise.

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the invention belongs. Also, terms, such as those defined in commonly used dictionaries, should be interpreted as having a meaning that is consistent with their meaning in the context of the relevant art and should not be interpreted in an idealized or overly formal sense unless expressly so defined herein.

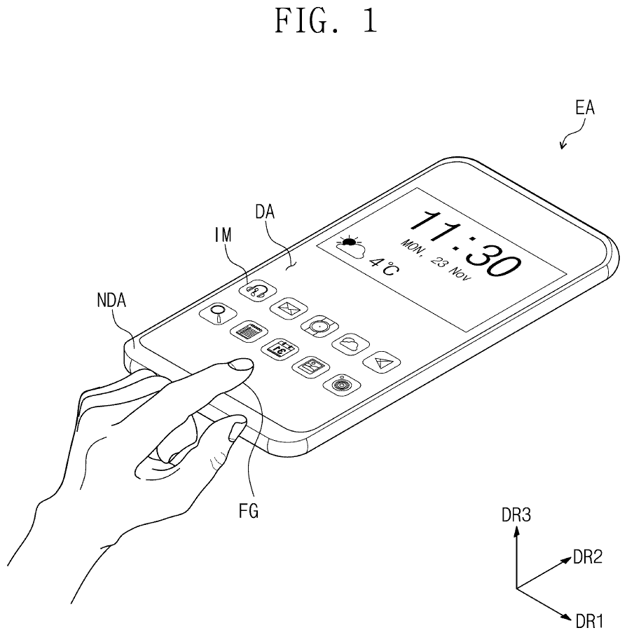

Hereinafter, an electronic apparatus, according to an embodiment, will be described with reference to the drawings. FIG. 1 is a perspective view illustrating an electronic apparatus, according to an embodiment.

In an embodiment and referring to FIG. 1, an electronic apparatus EA may be activated in response to an electrical signal and display images. For example, the electronic apparatus EA may be a personal computer, a laptop computer, a personal digital assistant, a game console, a portable electronic apparatus, a television, a monitor, an outdoor billboard, a car navigation unit, or a wearable apparatus, but an embodiment of the invention is not limited thereto. In FIG. 1, the electronic apparatus EA is exemplarily illustrated as a mobile phone.

In an embodiment, the electronic apparatus EA may be rigid or flexible. The wording “flexible” means having a bendable property. For example, the flexible electronic apparatus EA may include a curved apparatus, a slidable apparatus, a rollable apparatus, or a foldable apparatus.

The electronic apparatus EA, according to an embodiment, may display an image IM through a display region DA. The display region DA may include a flat surface defined by a first direction DR1 and a second direction DR2. The display region DA may further include a curved surface bent from at least one side of the flat surface defined by the first direction DR1 and the second direction DR2. A display surface, on which the image IM is displayed, may correspond to a front surface of the electronic apparatus EA. The image IM may include not only a dynamic image but also a static image.

In an embodiment, a non-display region NDA may be disposed adjacent to the display region DA, where the non-display region NDA may surround the display region DA. Accordingly, a shape of the display region DA may be substantially defined by the non-display region NDA. However, FIG. 1 is exemplarily illustrated. The non-display region NDA may be disposed adjacent to only one side of the display region DA or a portion thereof may be omitted. The electronic apparatus EA, according to an embodiment, may include a display region having various shapes, and is not limited to any one embodiment.

In an embodiment, on a plane, the electronic apparatus EA may have a rectangular shape which has short sides extending in the first direction DR1 and long sides extending in the second direction DR2 crossing the first direction DR1. However, the invention is not limited thereto, and on a plane, the electronic apparatus EA may have various shapes, such as a circular and polygonal shape.

In this specification, the first direction axis DR1 and the second direction axis DR2 may be directed orthogonal to each other, and a third direction axis DR3 may be directed in a normal direction of a plane defined by the first direction axis DR1 and the second direction axis DR2. A thickness direction of the electronic apparatus EA may be a direction that is directed parallel to the third direction axis DR3. A front surface (or upper surface) and a rear surface (or lower surface) may be opposed to each other in the third direction axis DR3, and a normal direction of each of the front surface (or upper surface) and the rear surface (or lower surface) may be directed parallel to the third direction axis DR3. The front surface (or upper surface) is referred to as a surface that is adjacent to a display surface on which the image IM is displayed, and the rear surface (or lower surface) is referred to as a surface that is spaced apart from the display surface on which the image IM is displayed. An upper side (or upper part, above) is referred to as a direction of getting closer to the display surface on which the image IM is displayed, and a lower side (or lower part, below) is referred to as a direction of getting farther away from the display surface on which the image IM is displayed.

A cross section is referred to as a surface that is directed parallel to the thickness direction DR3, and a plane is referred to as a surface that is directed perpendicular to the thickness direction DR3. A plane is referred to as a flat surface defined by the first direction axis DR1 and the second direction axis DR2.

The directions indicated by the first to third direction axes DR1, DR2, and DR3, respectively, illustrated herein have a relative concept, and may thus be changed to other directions. In addition, the directions indicated by the direction axes DR1, DR2, and DR3 may be referred to as first to third directions, respectively, and may be denoted as the same reference numerals or symbols.

In an embodiment, the electronic apparatus EA may detect an external input applied from the outside, where the external input may include various forms of inputs such as force, pressure, temperature, and light. The electronic apparatus EA, according to an embodiment, may detect a user's touch input FG applied from the outside. The user's touch input FG includes various forms of external inputs such as a part of a user's body, light, heat, or pressure. FIG. 1 illustrates that the user's input is a user's hand exerting pressure on a front surface. However, this is exemplarily illustrated, and as described above, the user's touch input FG may be provided in various forms. Additionally, the electronic apparatus EA may detect a user's input which is applied to a side surface or a rear surface of the electronic apparatus EA depending on a structure and is not limited to any one embodiment.

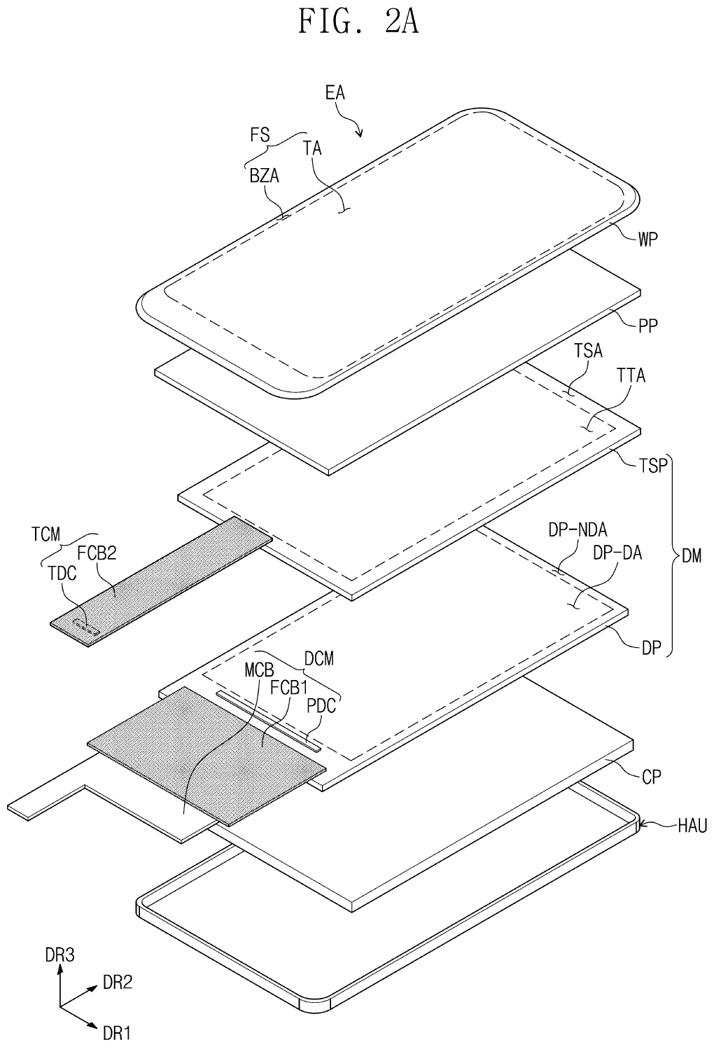

FIGS. 2A and 2B are exploded perspective views illustrating an electronic apparatus, according to an embodiment. FIG. 2A is a view illustrating an electronic apparatus EA in a state in which a first circuit board FCB1 and a second circuit board FCB2 to be described later are not bent, according to an embodiment. FIG. 2B is a view illustrating the electronic apparatus EA in a state in which the first circuit board FCB1 and the second circuit board FCB2 are bent, according to an embodiment.

In an embodiment and referring to FIGS. 2A and 2B, the electronic apparatus EA may include a display module DM, a driving control module DCM, an input control unit TCM, and a window member WP disposed on the display module DM. Additionally, the electronic apparatus EA may further include a light control layer PP, a lower member CP, and a housing HAU.

In an embodiment, in the electronic apparatus EA, the window member WP and the housing HAU may be coupled to constitute the exterior of the electronic apparatus EA, where the housing HAU may be disposed below the display module DM and the lower member CP. The housing HAU may include a material having relatively high rigidity. For example, the housing HAU may include a plurality of frames and/or plates composed of glass, plastic, or metal. The housing HAU may provide a predetermined accommodation space. The display module DM may be accommodated inside the accommodation space and may be protected against external impacts.

In an embodiment, the lower member CP may be disposed below the display module DM and may protect a display panel DP against external impacts, etc. The lower member CP may include a single layer or a plurality of layers.

In an embodiment, the display module DM may be activated in response to an electrical signal and may include the display panel DP and an input-sensing part TSP disposed on the display panel DP.

In an embodiment, the display panel DP may include a first active region DP-DA and a first peripheral region DP-NDA disposed adjacent to the first active region DP-DA. The first peripheral region DP-NDA may surround the first active region DP-DA. However, FIGS. 2A and 2B are exemplarily illustrated. In other embodiments, the first peripheral region DP-NDA may be disposed adjacent to only one side of the first active region DP-DA or a portion thereof may be omitted. The first active region DP-DA may correspond to the display region DA of the electronic apparatus EA illustrated in FIG. 1. The first peripheral region DP-NDA may correspond to the non-display region NDA of the electronic apparatus EA illustrated in FIG. 1. In this specification, it will be understood that when an element is referred to as corresponding to/overlapping another element, it is not limited to a case of having the same shape or area, and also may include a case of having different shapes and/or areas.

In an embodiment, the first active region DP-DA may be a region which is activated in response to an electrical signal and which displays images. The first peripheral region DP-NDA may be a region in which a driving circuit or a driving line for driving elements disposed in the first active region DP-DA, various types of signal lines, pads, etc., for providing electrical signals may be disposed. A bezel region BZA of the window member WP to be described later may prevent components of the display panel DP disposed in the first peripheral region DP-NDA from being viewed from the outside.

In an embodiment, the driving control module DCM may be disposed on a terminal portion of the display panel DP and may be disposed in the first peripheral region DP-NDA of the display panel DP. The driving control module DCM may include a main circuit board MCB, a first circuit board FCB1, and a panel driving circuit PDC.

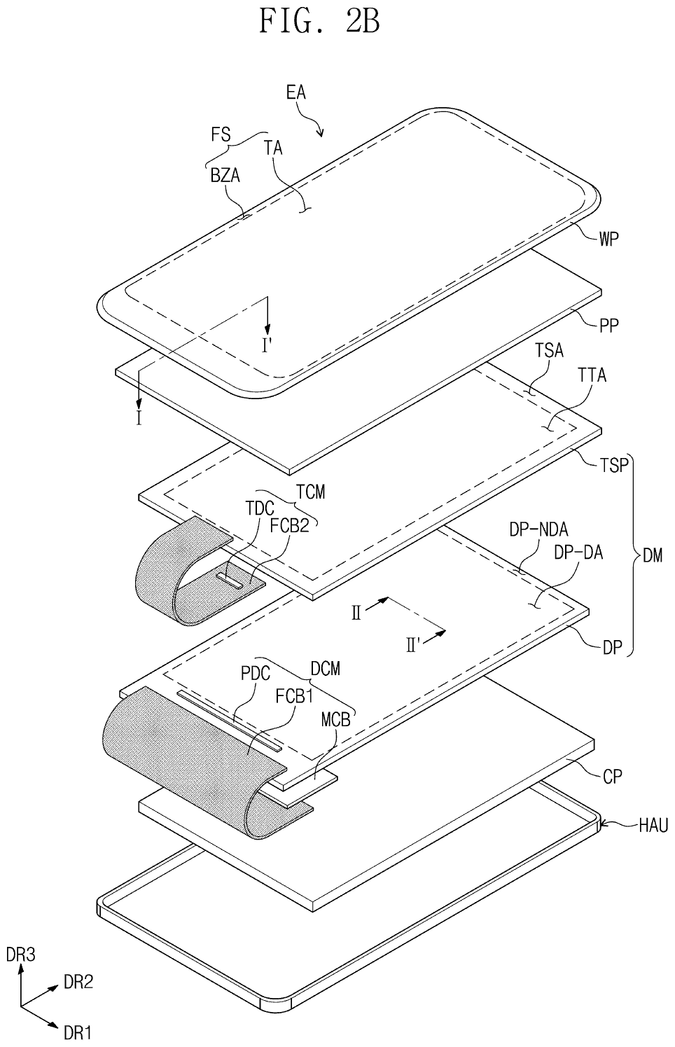

In an embodiment, the panel driving circuit PDC may be disposed in the first peripheral region DP-NDA and may be configured as an integrated circuit. Although not illustrated, a plurality of passive elements and a plurality of active elements may be mounted on the main circuit board MCB. The main circuit board MCB may be a rigid circuit board or a flexible circuit board, and the first circuit board FCB1 may be a flexible circuit board. The first circuit board FCB1 may be electrically connected to a pad PD (see FIG. 3) of the display panel DP.

In an embodiment, the first circuit board FCB1 may be disposed in the first peripheral region DP-NDA and may be connected to the terminal portion of the display panel DP to electrically connect the main circuit board MCB and the display panel DP. The first circuit board FCB1 may be bent. In an embodiment and referring to FIG. 2B, the first circuit board FCB1 may be bent such that one end of the first circuit board FCB1 is disposed adjacent to a front surface of the display panel DP and the other end of the first circuit board FCB1 is disposed adjacent to a rear surface of the display panel DP. In a bent state of the first circuit board FCB1, the main circuit board MCB may be disposed below the display panel DP. In a bent state of the first circuit board FCB1, the main circuit board MCB may be disposed adjacent to a rear surface of the display panel DP. The display module DM may be accommodated in the housing HAU while the first circuit board FCB1 is bent. Accordingly, the electronic apparatus EA has the reduced non-display region NDA and may thus have improved display quality.

In an embodiment, the input-sensing part TSP may include a second active region TTA and a second peripheral region TSA disposed adjacent to the second active region TTA, where the second peripheral region TSA may surround the second active region TTA. However, FIGS. 2A and 2B are exemplarily illustrated. In other embodiment, the second peripheral region TSA may be disposed adjacent to only one side of the second active region TTA or a portion thereof may be omitted. The second active region TTA of the input-sensing part TSP may correspond to the first active region DP-DA of the display panel DP and the second peripheral region TSA of the input-sensing part TSP may correspond to the first peripheral region DP-NDA of the display panel DP.

In an embodiment, the input-sensing part TSP may detect an external input, change the detected external input to a predetermined input signal, and provide the input signal to the display panel DP. For example, the input-sensing part TSP may be a touch-sensing part which detects a touch, where the input-sensing part TSP may recognize a direct touch by a user, an indirect touch by a user, a direct touch by an object, an indirect touch by an object, etc.

In an embodiment, the input-sensing part TSP may detect a position and/or intensity (pressure) of the touch input FG (see FIG. 1) applied from the outside. The input-sensing part TSP may have various structures or be composed of various materials and is not limited to any one embodiment. For example, the input-sensing part TSP may detect an external input in a capacitive manner. The display panel DP may receive input signals from the input-sensing part TSP and generate images corresponding to the input signals.

In an embodiment, the input control unit TCM may be disposed on a terminal portion of the input-sensing part TSP. The input control unit TCM may be disposed in the second peripheral region TSA of the input-sensing part TSP. The input control unit TCM may include a second circuit board FCB2 and an input driving circuit TDC. The input driving circuit TDC may be mounted on the second circuit board FCB2 and may be configured as an integrated circuit. The second circuit board FCB2 may be disposed on a terminal portion of the input-sensing part TSP to electrically connect the main circuit board MCB and the input-sensing part TSP. The second circuit board FCB2 may be electrically connected to a sensing pad TPD (see FIG. 3) of the input-sensing part TSP.

In an embodiment, the second circuit board FCB2 may be a flexible circuit board which may be bent, similarly to the first circuit board FCB1. Referring to FIG. 2B, the second circuit board FCB2 may be bent such that one end of the second circuit board FCB2 is disposed adjacent to a front surface of the input-sensing part TSP and the other end of the second circuit board FCB2 is disposed adjacent to a rear surface of the input-sensing part TSP. The display module DM is accommodated in the housing HAU while the second circuit board FCB2 is bent. Accordingly, the electronic apparatus EA has the reduced non-display region NDA and may thus have an improved display quality.

In an embodiment, the light control layer PP may be disposed between the display module DM and the window member WP and may be an anti-reflective layer which reduces reflectance for external light that is incident from the outside of the display module DM. The light control layer PP may include a polarization plate or a color filter layer. For example, the light control layer PP may include at least one of a retarder, a polarizer, a polarization film, or a polarization filter. In an other embodiment, the light control layer PP may include a plurality of color filters disposed in a predetermined arrangement. In still another embodiment, the light control layer PP may be omitted.

In an embodiment, a front surface FS of the window member WP may correspond to a front surface of the electronic apparatus EA and may include the bezel region BZA and a transmission region TA.

In an embodiment, the transmission region TA may overlap at least a portion of the first active region DP-DA of the display panel DP, where the transmission region TA may be an optically transparent region. The image IM (see FIG. 1) may be provided to a user through the transmission region TA.

In an embodiment, the bezel region BZA may be a region having a relatively lower light transmittance than the transmission region TA and may define a shape of the transmission region TA. The bezel region BZA may be disposed adjacent to the transmission region TA and may surround the transmission region TA. The bezel region BZA may have a predetermined color. The bezel region BZA may cover the first peripheral region DP-NDA of the display panel DP and may block the first peripheral region DP-NDA from being viewed from the outside. However, the invention is not limited to what is illustrated in the drawings. In another embodiment, the bezel region BZA may be disposed adjacent to only one side of the transmission region TA, or a portion thereof may be omitted.

FIG. 3 is a cross-sectional view illustrating a portion taken along line I-I′ of FIG. 2B, according to an embodiment. Referring to FIG. 3, the electronic apparatus EA may further include an optical adhesive layer AL1 disposed between the light control layer PP and the window member WP. The electronic apparatus EA may further include a module adhesive layer AL2 disposed between the display module DM and the light control layer PP. For example, the optical adhesive layer AL1 and the module adhesive layer AL2 may each include a pressure sensitive adhesive film (PSA), an optically clear adhesive film (OCA), or an optically clear resin (OCR). However, this is exemplarily illustrated, and the optical adhesive layer AL1 and the module adhesive layer AL2 may each include a typical bonding agent/adhesive agent known in the art.

In an embodiment, the electronic apparatus EA may further include a protective film PF disposed between the display panel DP and the lower member CP. Since the protective film PF is disposed adjacent to a lower surface of the display panel DP, the display panel DP may be protected against impacts. The protective film PF may include a flexible plastic material. For example, the protective film PF may include polyethylene terephthalate (PET).

In an embodiment, the lower member CP may include a support layer SP, a cushion layer CSL disposed on the support layer SP, and a barrier layer BEL disposed on the cushion layer CSL. A configuration of the lower member CP is not limited to what is illustrated in FIG. 3, etc., and may vary according to the size, shape or operating characteristics, etc., of the electronic apparatus EA. For example, in another embodiment, a part of the support layer SP, the cushion layer CSL, and the barrier layer BEL may be omitted, or a stacking order thereof may be changed to another order different from what is illustrated in FIG. 3. In still another embodiment, additional components, in addition to the illustrated components, may be further included.

In an embodiment, the support layer SP may support components (for example, the display panel DP) disposed on an upper part of the support layer SP. The support layer SP may include a metal material or a polymer material. For example, the support layer SP may be formed of stainless steel, aluminum, or alloys thereof. In another embodiment, the support layer SP may be formed of a polymer material.

In an embodiment, the cushion layer CSL may absorb an impact transmitted from below the display panel DP, where the cushion layer CSL may include an elastomer such as a sponge, a foam, or a urethane resin. Additionally, the cushion layer CSL may be formed of at least one of an acylate-based polymer, a urethane-based polymer, a silicone-based polymer, or an imide-based polymer.

In an embodiment, the barrier layer BEL may enhance resistance against a compressive force caused by external pressure and may serve to prevent the display panel DP from being deformed. The barrier layer BEL may be a colored film having a low transmittance with respect to light. Accordingly, the barrier layer BEL may prevent components disposed therebelow from being viewed. The barrier layer BEL may include a flexible synthetic resin film. For example, the barrier layer BEL may include polyimide or polyethyleneterephthalate. However, this is presented as an example, and a material of the barrier layer BEL is not limited thereto.

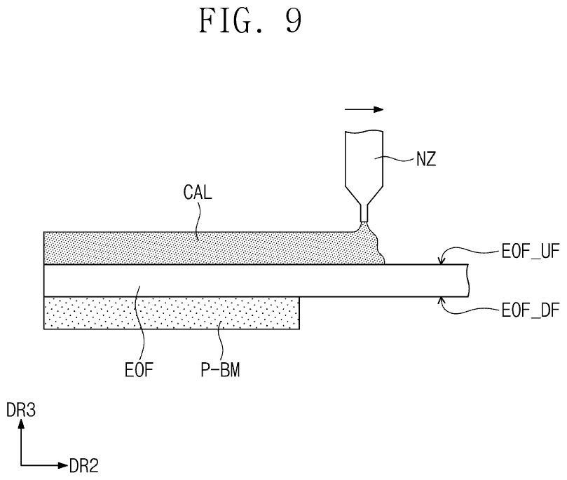

In an embodiment, the window member WP may include a support film EOF, a coating window CW disposed on the support film EOF, and a light-blocking pattern BM spaced apart from the coating window CW with the support film EOF disposed therebetween. The coating window CW may be formed of coating liquid CAL (see FIG. 9). The coating window CW may be formed by curing the coating liquid CAL (see FIG. 9) including an organic material. The coating window CW may not include a glass substrate.

In an embodiment, the coating window CW may be optically transparent and may have a transmittance of about 90% or more with respect to light having a visible light wavelength range. The coating window CW may have a yellow index of about 1 or less, and the yellow index may be measured via the ASTM E313 method. Since the coating window CW formed by curing the coating liquid CAL (see FIG. 9) exhibits a high light transmittance in a visible light wavelength range and a low yellow index property, the coating window CW may replace a typical glass substrate, and thus the electronic apparatus EA, according to an embodiment, including the coating window CW may achieve an excellent display quality.

In an embodiment, the coating window CW may have a pencil hardness of about 9H or more, a bright spot occurrence height of about 11 cm or more, as evaluated with a Dupont impact tester, and may have an indentation modulus (EIT) of about 800 MPa or more, as measured with a Nano indenter. The coating window CW formed by providing the coating liquid CAL (see FIG. 9) satisfies the above-described mechanical properties and may thus exhibit excellent durability.

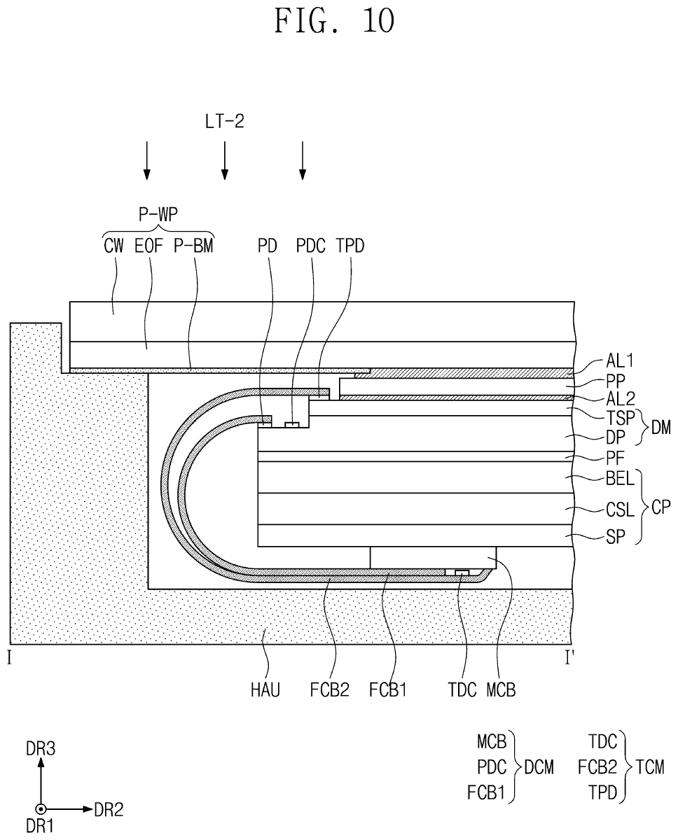

In an embodiment, the coating window CW and the support film EOF may each have a transmittance of about 50% or more with respect to near-infrared (NIR) rays. The coating window CW and the support film EOF may each have a transmittance of about 50% or more with respect to light having a wavelength range of about 700 nm to about 1000 nm. The light having a wavelength range of about 700 nm to about 1000 nm corresponds to near-infrared rays. Accordingly, in an electronic apparatus manufacturing method to be described later, near-infrared rays LT-2 (see FIG. 10) provided during a step of forming the light-blocking pattern BM may pass through the coating window CW and the support film EOF and be provided to a preliminary light-blocking pattern P-BM (see FIG. 10).

In an embodiment, the coating window CW may be directly disposed on the support film EOF. In this specification, the wording, “an element is referred to as being directly disposed/provided on another element” means that there is no intervening element therebetween. That is, the wording, “an element is ‘directly disposed on/provided to’ another element” may mean that an element is ‘in contact with’ another element.

In an embodiment, on a plane, the support film EOF may entirely overlap the coating window CW, where a portion of an edge region of each of the support film EOF and the coating window CW may not overlap the display module DM and may overlap the housing HAU. A portion of an edge region of each of the support film EOF and the coating window CW may be disposed on the housing HAU.

In an embodiment, the support film EOF may serve as a base layer when the coating liquid CAL (see FIG. 9) for forming the coating window CW is provided. Additionally, when the coating liquid CAL (see FIG. 9) is provided, the support film EOF may prevent the coating liquid CAL (see FIG. 9) from flowing between first and second circuit boards FCB1 and FCB2, respectively. If the coating liquid flows to the first and second circuit boards and is cured, cracks occur when the first and second circuit boards are bent. Since the electronic apparatus EA, according to an embodiment, includes the support film EOF, the coating liquid CAL (see FIG. 9) is prevented from flowing to the circuit boards FCB1 and FCB2, and thus the above-described cracks may not occur.

In an embodiment, the support film EOF may be optically transparent and may include an organic material. For example, the support film EOF may include polyimide (PI) and polyethylene terephthalate (PET). However, this is presented as an example, and a material included in the support film EOF is not limited thereto.

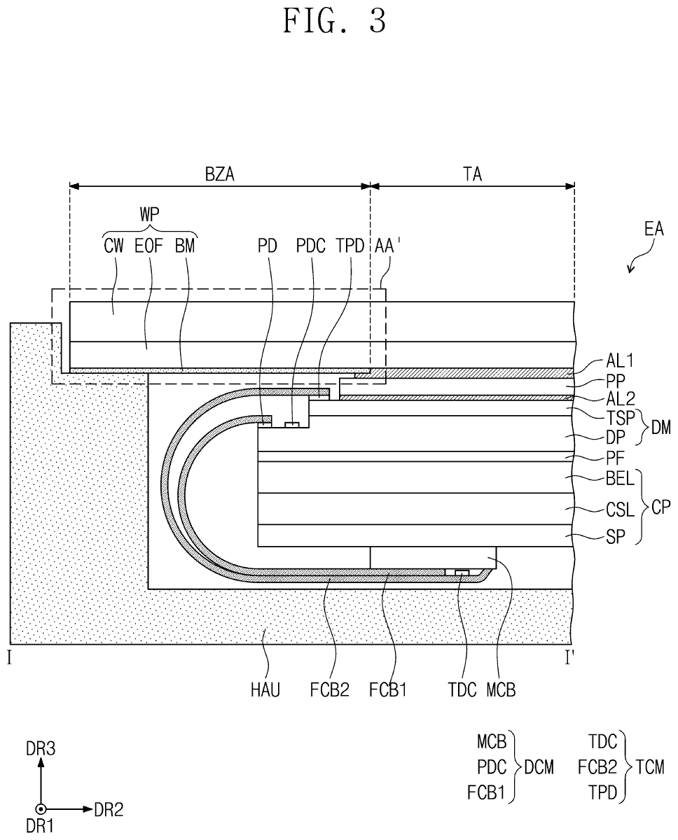

In an embodiment, the light-blocking pattern BM may be disposed between the light control layer PP and the support film EOF, where the light-blocking pattern BM may be directly disposed on a lower surface EOF_DF (see FIG. 4) of the support film EOF. The light-blocking pattern BM may have a predetermined color. The light-blocking pattern BM may correspond to the non-display region NDA (see FIG. 1). The light-blocking pattern BM is disposed so as to correspond to the first peripheral region DP-NDA (see FIGS. 2A and 2B) and the second peripheral region TSA (see FIGS. 2A and 2B), and thus components in the first peripheral region DP-NDA (see FIGS. 2A and 2B) and the second peripheral region TSA (see FIGS. 2A and 2B) may be prevented from being viewed from the outside. The light-blocking pattern BM may define the bezel region BZA of the window member WP.

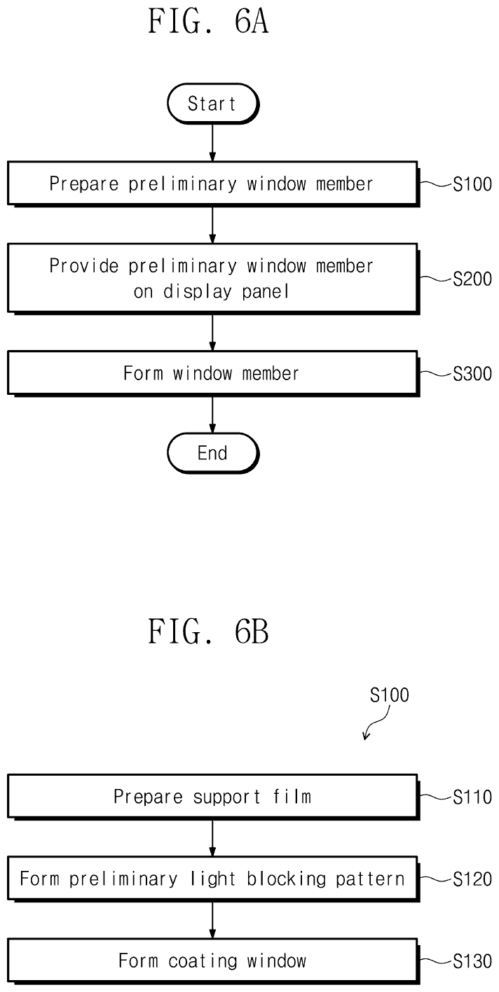

The light-blocking pattern BM may be formed of a light-blocking composition BC (see FIG. 7) including a black colorant, an ultraviolet photoinitiator, a near-infrared photosensitizer, a near-infrared photoinitiator, and an adhesive resin. The light-blocking pattern BM may be formed by photocuring the light-blocking composition BC (see FIG. 7). In an embodiment, the colorant includes a pigment or a dye. In an embodiment, an adhesive resin is referred to as a resin containing a functional group which serves as an adhesive agent.

For example, the ultraviolet photoinitiator may include an iodonium salt. The near-infrared photosensitizer may include a heptamethine cyanine dye. The near-infrared photoinitiator may include a coumarinacyl anilinium salt (CAA salt). The adhesive resin may include at least one of a silicone-based resin, a urethane-based resin, or an acryl-based resin. However, this is presented as an example and, in another embodiment, the light-blocking composition BC (see FIG. 7) may further include another material known in the art, as long as not degrading physical properties of the light-blocking pattern BM.

The light-blocking pattern BM may have an optical density (OD) of about 3 or more. The light-blocking pattern BM having an optical density of about 3 or more prevents light leakage, and thus it is possible to improve the display quality of the electronic apparatus EA. The light-blocking pattern BM may have an adhesive force of about 5B or more with respect to the support film EOF, and the adhesive force may be measured via the ASTM D3359 method. The light-blocking pattern BM may have an adhesive force of about 5B or more with respect to the housing HAU, and the adhesive force may be measured through the ASTM D3359 method. In an embodiment, the light-blocking pattern BM formed of the light-blocking composition BC (see FIG. 7) including an adhesive resin may serve as an adhesive agent when the window member WP is coupled to the housing HAU. The light-blocking pattern BM and the housing HAU may be physically/chemically coupled. The light-blocking pattern BM, satisfying the above-described adhesive force, stably couples the window member WP and the housing HAU, and thus it is possible to exhibit excellent reliability.

FIG. 4 is an enlarged cross-sectional view illustrating region AA′ of FIG. 3, according to an embodiment. In an embodiment and referring to FIG. 4, the optical adhesive layer AL1 may have a thickness TH4 in the range of about 100 μm to about 200 μm. The optical adhesive layer AL1 satisfying the above-described thickness range may stably couple the light control layer PP and a member (for example, the support film EOF) adjacent to the light control layer PP without an increase in a thickness of the electronic apparatus EA.

In an embodiment, the light-blocking pattern BM may be in contact with the optical adhesive layer AL1, where a side surface BM_SF of the light-blocking pattern BM may be in contact with the optical adhesive layer AL1. The light-blocking pattern BM may be disposed between the support film EOF and the optical adhesive layer AL1. The light-blocking pattern BM formed of the light-blocking composition BC (see FIG. 7) including an adhesive resin is in contact with the optical adhesive layer AL1, and thus a coupling force between the support film EOF and the optical adhesive layer AL1 may be improved to exhibit excellent reliability.

In an embodiment, the light-blocking pattern BM may include an upper surface BM_UF, a lower surface BM_DF, and a side surface BM_SF. The upper surface BM_UF and the lower surface BM_DF of the light-blocking pattern BM may be spaced apart from each other in the thickness direction DR3. The side surface BM_SF may be disposed between the upper surface BM_UF and the lower surface BM_DF. The upper surface BM_UF, the lower surface BM_DF, and the side surface BM_SF of the light-blocking pattern BM may have an integral shape.

In an embodiment, the upper surface BM_UF of the light-blocking pattern BM may be in contact with the support film EOF. The light-blocking pattern BM may be formed by providing the light-blocking composition BC (see FIG. 7) directly on the lower surface EOF_DF of the support film EOF. Accordingly, the upper surface BM_UF of the light-blocking pattern BM may be in contact with the lower surface EOF_DF of the support film EOF.

In an embodiment, one region of the lower surface BM_DF of the light-blocking pattern BM may be in contact with the optical adhesive layer AL1. Another region of the lower surface BM_DF of the light-blocking pattern BM may be in contact with the housing HAU. Since the light-blocking pattern BM may be in contact with the housing HAU, the window member WP may be stably coupled to the housing HAU.

In an embodiment, the light-blocking pattern BM may have a thickness TH1 in the range of about 3 μm to about 50 μm. The light-blocking pattern having a thickness of less than about 3 μm may not stably couple the window member and the housing, and the light-blocking pattern having a thickness of greater than about 50 μm increases a thickness of the electronic apparatus. Unlike this, the light-blocking pattern BM having a thickness TH1 in the range of about 3 μm to about 50 μm may stably couple the window member WP and the housing HAU without an increase in a thickness of the electronic apparatus EA.

In an embodiment, the support film EOF may include an upper surface EOF_UF and the lower surface EOF_DF spaced apart from each other in the thickness direction DR3. The coating window CW may be disposed on the upper surface EOF_UF of the support film EOF, and the light-blocking pattern BM may be disposed on the lower surface EOF_DF of the support film EOF. The side surface BM_SF of the light-blocking pattern BM and the lower surface EOF_DF of the support film EOF may define a stepped portion SP-a, and the optical adhesive layer AL1 may be disposed while covering the stepped portion SP-a.

In an embodiment, a first edge CW_EG of the coating window CW, a second edge EOF_EG of the support film EOF, and a third edge BM_EG of the light-blocking pattern BM may be disposed parallel to each other in the thickness direction DR3. The first edge CW_EG of the coating window CW, the second edge EOF_EG of the support film EOF, and the third edge BM_EG of the light-blocking pattern BM may overlap. Since the coating window CW is formed by providing the coating liquid CAL (see FIG. 9) on the upper surface EOF_UF of the support film EOF and the light-blocking pattern BM is formed by providing the light-blocking composition BC (see FIG. 7) on the lower surface EOF_DF of the support film EOF, the first edge CW_EG of the coating window CW, the second edge EOF_EG of the support film EOF, and the third edge BM_EG of the light-blocking pattern BM may be directed parallel to each other in the thickness direction DR3.

In an embodiment, the support film EOF may have a thickness TH2 in the range of about 100 μm to about 200 μm. The coating window CW may have a thickness TH3 in the range of about 300 μm to about 800 μm. The support film EOF and the coating window CW satisfying the above-described thickness ranges may exhibit favorable durability without an increase in a thickness of the electronic apparatus EA.

In an embodiment, in a typical electronic apparatus, a light-blocking pattern is provided between a support film and a coating window, where the light-blocking pattern is formed on one surface of the support film, and then the coating window is formed on the light-blocking pattern. When forming the coating window, coating quality deteriorates due to a stepped portion defined by the support film and the light-blocking pattern on one surface of the support film, and the surface quality of the coating window, which is the uppermost member of the electronic apparatus, deteriorates. Also, in a typical electronic apparatus, a housing is coupled to a window member by providing and curing an additional adhesive agent on the housing. Heat is provided during the step of curing the additional adhesive agent, and a high temperature (about 130° C. or more) causes damage to components such as a display panel, etc.

In an embodiment, the electronic apparatus EA may include the light-blocking pattern BM spaced apart from the coating window CW with the support film EOF disposed therebetween, and the light-blocking pattern BM may be formed by photocuring the light-blocking composition BC (see FIG. 7) including an adhesive resin. Accordingly, the light-blocking pattern BM may couple the housing HAU and the window member WP without an additional adhesive agent, and thus it is possible to prevent damage of components such as the display panel DP, etc. Since an additional adhesive is not included, the electronic apparatus EA, according to an embodiment, may have a reduced thickness and exhibit an excellent processability. Since the light-blocking pattern BM is disposed below the support film EOF, light leakage may be prevented, and thus excellent display quality may be achieved. Also, the light-blocking pattern BM and the coating window CW are respectively formed on different surfaces (lower surface or upper surface) of the support film EOF, and thus the surface quality may be improved.

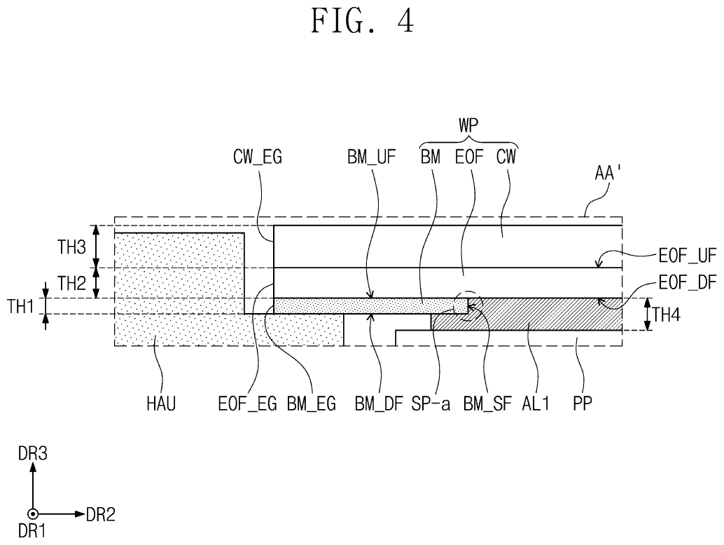

FIG. 5 is a cross-sectional view illustrating a portion taken along line II-II′ of FIG. 2B, according to an embodiment. FIG. 5 may be a cross-sectional view illustrating the display panel DP, according to an embodiment. In an embodiment and referring to FIG. 5, the display panel DP may include a base substrate BS, a circuit layer DP-CL disposed on the base substrate BS, a display element layer DP-EL disposed on the circuit layer DP-CL, and an encapsulation layer TFE covering the display element layer DP-EL. The components of the display panel DP illustrated in FIG. 5 are illustrated as examples, and components of the display panel DP are not limited thereto. For example, in an embodiment, the display panel DP may include a liquid crystal display element, and in another embodiment, the encapsulation layer TFE may be omitted.

In an embodiment, the base substrate BS may provide a base surface on which the circuit layer DP-CL is disposed and may be a flexible substrate which is bendable, foldable, rollable, etc. The base substrate BS may be a glass substrate, a metal substrate, a polymer substrate, etc. However, the invention is not limited thereto, and the base substrate BS may include an inorganic layer, an organic layer, or a composite material layer.

In an embodiment, the base substrate BS may include a single layer or a plurality of layers. For example, the base substrate BS may include a first synthetic resin layer, a multi- or single-layered inorganic layer, or a second synthetic resin layer disposed on the multi- or single-layered inorganic layer. The first synthetic resin layer and the second synthetic resin layer may each include a polyimide-based resin. Additionally, the first synthetic resin layer and the second synthetic resin layer may each include at least one among an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, and a perylene-based resin. In this specification, a “˜˜based” resin is considered as including a functional group of “˜˜”. For example, the acryl-based resin is a resin including an acrylic group.

In an embodiment, the display panel DP may include a transistor TR and a light-emitting element ED, where the transistor TR and the light-emitting element ED may be disposed on the base substrate BS. FIG. 5 illustrates one transistor TR, but the display panel DP may substantially include at least one capacitor and a plurality of transistors for driving the light-emitting element ED.

In an embodiment, the circuit layer DP-CL may be disposed on the base substrate BS and may include a shielding electrode BML, the transistor TR, a connection electrode CNE, and a plurality of insulating layers BFL and INS1 to INS6. The plurality of insulating layers BFL and INS1 to INS6 may include a buffer layer BFL and insulating layers INS1 to INS6. However, the stacked structure of the circuit layer DP-CL illustrated in FIG. 5 is presented as an example, and the stacked structure of the circuit layer DP-CL may be changed according to a configuration of the display panel DP and a process for the circuit layer DP-CL, etc.

In an embodiment, the shielding electrode BML may be disposed on the base substrate BS and may overlap the transistor TR. The shielding electrode BML may block light incident onto the transistor TR from below the display panel DP to protect the transistor TR. The shielding electrode BML may include a conductive material. When a voltage is applied to the shielding electrode BML, a threshold voltage of the transistor TR disposed on the shielding electrode BML may be maintained. However, the invention is not limited thereto, and the shielding electrode BML may be a floating electrode. Additionally, the shielding electrode BML may be omitted.

In an embodiment, the buffer layer BFL may be disposed on the base substrate BS and may cover the shielding electrode BML. The buffer layer BFL may include an inorganic layer and may improve a coupling force between the base substrate BS and a semiconductor pattern or a conductive pattern, which is disposed on the buffer layer BFL.

In an embodiment, the transistor TR may include a source S1, a channel C1, a drain D1, and a gate G1, where the source S1, the channel C1, and the drain D1 of the transistor TR may be formed from a semiconductor pattern. The semiconductor pattern of the transistor TR may include polysilicon, amorphous silicon, or a metal oxide. However, any material having semiconductor properties may be used without any limitation and is not limited to any one embodiment.

In an embodiment, the semiconductor pattern may include a plurality of regions divided according to a conductivity level. In the semiconductor pattern, a region, which is doped with a dopant or in which a metal oxide is reduced, may have a high conductivity, and may serve substantially as a source electrode and a drain electrode of the transistor TR. A highly conductive region of the semiconductor pattern may correspond to the source S1 and the drain D1 of the transistor TR. In the semiconductor pattern, a region, which is undoped or lightly doped or which has a low conductivity due to a non-reduced metal oxide, may correspond to the channel C1 (or active) of the transistor TR.

In an embodiment, the first insulating layer INS1 may cover the semiconductor pattern of the transistor TR and may be disposed on the buffer layer BFL. The gate G1 of the transistor TR may be disposed on the first insulating layer INS1. On a plane, the gate G1 may overlap the channel C1 of the transistor TR. The gate G1 may function as a mask during the process of doping the semiconductor pattern of the transistor TR.

In an embodiment, the second insulating layer INS2 may cover the gate G1 and be disposed on the first insulating layer INS1. The third insulating layer INS3 may be disposed on the second insulating layer INS2.

In an embodiment, the connection electrode CNE may include a first connection electrode CNE1 and a second connection electrode CNE2 which electrically connect the transistor TR and the light-emitting element ED. However, a configuration of the connection electrode CNE which electrically connects the transistor TR to the light-emitting element ED is not limited to the configuration described above. In various embodiments, either of the first connection electrode CNE1 or the second connection electrode CNE2 may be omitted, or an additional connection electrode may be further included.

In an embodiment, the first connection electrode CNE1 may be disposed on the third insulating layer INS3 and may be connected to the drain D1 via a first contact hole CH1 passing through the insulating layers INS1 to INS3. The fourth insulating layer INS4 may cover the first connection electrode CNE1 and be disposed on the third insulating layer INS3. The fifth insulating layer INS5 may be disposed on the fourth insulating layer INS4.

In an embodiment, the second connection electrode CNE2 may be disposed on the fifth insulating layer INS5 and may be connected to the first connection electrode CNE1 via a second contact hole CH2 passing through the insulating layers INS4 and INS5. The sixth insulating layer INS6 may cover the second connection electrode CNE2 and be disposed on the fifth insulating layer INS5.

In an embodiment, the insulating layers INS1 to INS6 may each include an inorganic layer or an organic layer. For example, the inorganic layer may include at least one among aluminum oxide, titanium oxide, silicon oxide, silicon oxynitride, zirconium oxide, and hafnium oxide. The organic layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin.

In an embodiment, the display element layer DP-EL may include a pixel-defining film PDL and the light-emitting element ED, where the light-emitting element ED may include a first electrode AE, a hole control layer HCL, a light-emitting layer EML, an electron control layer TCL, and a second electrode CE.

In an embodiment, the first electrode AE may be disposed on the sixth insulating layer INS6 and may be connected to the second connection electrode CNE2 via a third contact hole CH3 passing through the sixth insulating layer INS6. The first electrode AE may be electrically connected to the drain D1 of the transistor TR via the connection electrodes CNE1 and CNE2.

In an embodiment, the first electrode AE may be formed of a metal material, a metal alloy, or a conductive compound and may be an anode or a cathode. However, the invention is not limited thereto. Also, the first electrode AE may be a pixel electrode. The first electrode AE may be a transmissive electrode, a transflective electrode, or a reflective electrode. The first electrode AE may include at least one selected from among Ag, Mg, Cu, Al, Pt, Pd, Au, Ni, Nd, Ir, Cr, Li, Ca, LiF, Mo, Ti, W, In, Sn, or Zn; a compound of two or more materials selected from there-among; a mixture of two or more materials selected from there-among; or an oxide thereof.

In an embodiment, when the first electrode AE is the transmissive electrode, the first electrode AE may include a transparent metal oxide, for example, indium tin oxide (ITO), indium zinc oxide (IZO), zinc oxide (ZnO), indium tin zinc oxide (ITZO), etc. When the first electrode AE is the transflective electrode or the reflective electrode, the first electrode AE may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, W, or a compound or mixture thereof (for example, a mixture of Ag and Mg). In another embodiment, the first electrode AE may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), etc. For example, the first electrode AE may have a three-layered structure of ITO/Ag/ITO, but is not limited thereto. In addition, an embodiment of the inventive concept is not limited thereto, and the first electrode AE may include the above-described metal materials, a combination of two or more metal materials selected from there-among, oxides of the above-described metal materials, etc.

In an embodiment, the pixel-defining film PDL may be disposed on the sixth insulating layer INS6. A light-emitting opening PX_OP which exposes a portion of the first electrode AE may be defined in the pixel-defining film PDL. A portion, of the first electrode AE, which is exposed by the light-emitting opening PX_OP may be defined as a light-emitting region LA.

In an embodiment, the first active region DP-DA of the display panel DP may include the light-emitting region LA and a light-blocking region NLA. A region, in which the pixel-defining film PDL is disposed, may correspond to the light-blocking region NLA. The light-blocking region NLA may surround the light-emitting region LA within the first active region DP-DA.

In an embodiment, the hole control layer HCL may be disposed on the first electrode AE and the pixel-defining film PDL, where the hole control layer HCL may be provided as a common layer overlapping the light-emitting region LA and the light-blocking region NLA. In another embodiment, the hole control layer HCL may be provided only in a region corresponding to the light-emitting opening PX_OP. The hole control layer HCL may include at least one among a hole transport layer, a hole injection layer, and an electron blocking layer. The hole control layer HCL may include a typical hole injection material and/or a typical hole transport material.

In an embodiment, the light-emitting layer EML may be disposed on the hole control layer HCL, where the light-emitting layer EML may be disposed in a region corresponding to the light-emitting opening PX_OP. In another embodiment, the light-emitting layer EML may be provided as a common layer. The light-emitting layer EML may include an organic light-emitting material and/or an inorganic light-emitting material. The light-emitting layer EML may emit light having one color of red, green, or blue. For example, the light-emitting layer EML may emit blue light.

In an embodiment, the electron control layer TCL may be disposed on the light-emitting layer EML and may be provided as a common layer overlapping the light-emitting region LA and the light-blocking region NLA. In another embodiment, the electron control layer TCL may be provided only in a region corresponding to the light-emitting opening PX_OP, where the electron control layer TCL may include at least one among an electron transport layer, an electron injection layer, and a hole blocking layer. The electron control layer TCL may include a typical electron injection material and/or a typical electron transport material.

In an embodiment, the second electrode CE may be disposed on the electron control layer TCL and may be provided as a common layer overlapping the light-emitting region LA and the light-blocking region NLA.

The second electrode CE may be a common electrode, where the second electrode CE may be a cathode or an anode. However, the invention is not limited thereto. For example, in another embodiment, when the first electrode AE is an anode, the second electrode CE may be a cathode, and when the first electrode AE is a cathode, the second electrode CE may be an anode.

In an embodiment, the second electrode CE may be a transmissive electrode, a transflective electrode, or a reflective electrode. When the second electrode CE is the transmissive electrode, the second electrode CE may be formed of a transparent metal oxide, for example, indium tin oxide (ITO), indium zinc oxide (IZO), zinc oxide (ZnO), indium tin zinc oxide (ITZO), etc.

In an embodiment, when the second electrode CE is the transflective electrode or the reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (for example, AgMg, AgYb, or MgYb). In another embodiment, the second electrode CE may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), etc. For example, the second electrode CE may include the above-described metal materials, a combination of two or more metal materials selected from there-among, oxides of the above-described metal materials, etc.

In an embodiment, the encapsulation layer TFE may be disposed on the display element layer DP-EL, where the encapsulation layer TFE may be disposed on the second electrode CE and may cover the light-emitting element ED. The encapsulation layer TFE may include a plurality of thin films. For example, the encapsulation layer TFE may include inorganic films, disposed on the second electrode CE, and an organic film disposed between the inorganic films. The inorganic film may protect the light-emitting element ED against moisture/oxygen, and the organic film may protect the light-emitting element ED against foreign substances such as dust particles.

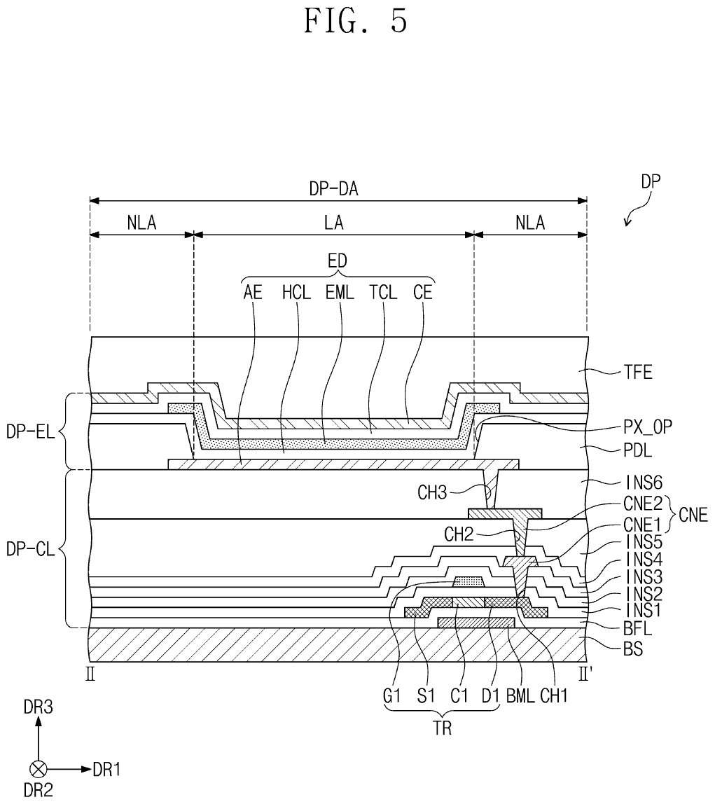

In an embodiment, an electronic apparatus may be manufactured through an electronic apparatus manufacturing method. FIGS. 6A and 6B are flowcharts illustrating an electronic apparatus manufacturing method, according to an embodiment. FIGS. 7 to 10 are views schematically illustrating electronic apparatus manufacturing steps, according to an embodiment. Hereinafter, with regard to the descriptions of FIGS. 6A to 10, the contents duplicated with those described with the references to FIGS. 1 to 5 will not be explained again, and the following description will be mainly focused on the differences.

In an embodiment and referring to FIG. 6A, the electronic apparatus manufacturing method may include the steps of preparing a preliminary window member (S100), providing the preliminary window member on a display panel (S200), and forming a window member (S300). A preliminary window member P-WP (see FIG. 10) may include a support film EOF (see FIG. 10), a coating window CW (see FIG. 10) disposed on the support film EOF (see FIG. 10), and a preliminary light-blocking pattern P-BM (see FIG. 10) spaced apart from the coating window CW (see FIG. 10) with the support film EOF (see FIG. 10) therebetween. Referring to FIG. 6B, preparing the preliminary window member (S100) may include the steps of preparing the support film (S110), forming the preliminary light-blocking pattern (S120), and forming the coating window (S130).

FIGS. 7 to 9 are views schematically illustrating the step of preparing the preliminary window member P-WP (see FIG. 10), according to an embodiment. In an embodiment, a light-blocking composition BC may be provided to form the preliminary light-blocking pattern P-BM (see FIG. 10). Referring to FIG. 7, the light-blocking composition BC may be provided on one surface EOF_DF of the support film EOF. The light-blocking composition BC may be directly provided on the one surface EOF_DF of the support film EOF, where the one surface EOF_DF of the support film EOF may be the lower surface EOF_DF of the support film EOF (see FIG. 4). In the thickness direction DR3, the other surface EOF_UF of the support film EOF spaced apart from the one surface EOF_DF of the support film EOF may be the upper surface EOF_UF of the support film EOF (see FIG. 4).

In an embodiment, the light-blocking composition BC may include a black colorant, an ultraviolet photoinitiator, a near-infrared photosensitizer, a near-infrared photoinitiator, and an adhesive resin. The light-blocking composition BC may be provided through an inkjet printing method or a dispensing method. FIG. 7 illustrates that the light-blocking composition BC is provided through a nozzle NZ, but an apparatus for providing the light-blocking composition BC is not limited thereto.

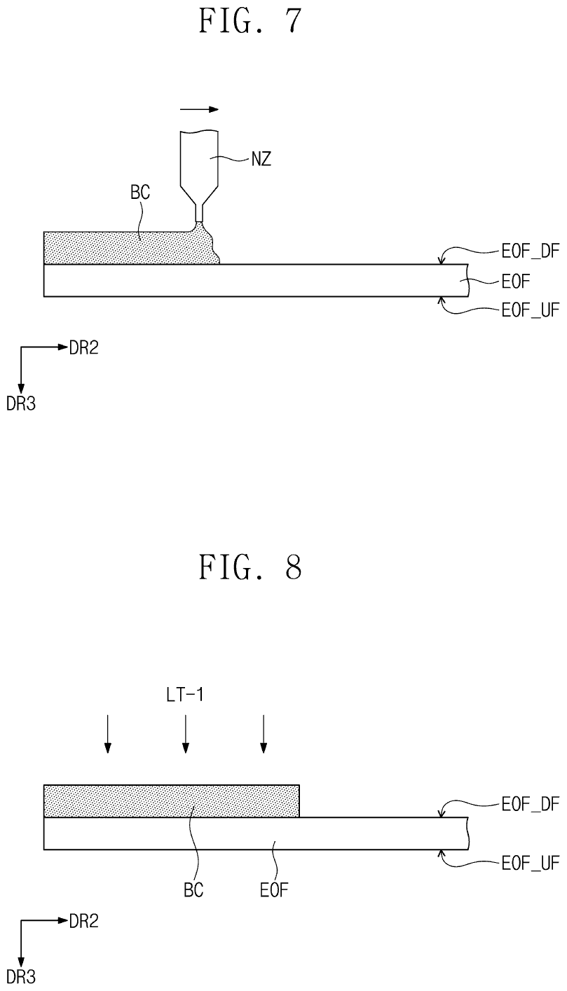

In an embodiment and referring to FIG. 8, the light-blocking composition BC provided on one surface EOF_DF of a support film EOF may be irradiated with ultraviolet rays LT-1. The light-blocking composition BC is cured by the ultraviolet rays LT-1, and a preliminary light-blocking pattern P-BM (see FIG. 9) may be formed. The step of irradiating with the ultraviolet rays LT-1 may be a temporary curing step, and a shape of the preliminary light-blocking pattern P-BM may be maintained through the temporary curing step. A total amount of the ultraviolet rays LT-1 emitted to the light-blocking composition BC may be about 100 mJ or less. For example, the total amount of the ultraviolet rays LT-1 emitted to the light-blocking composition BC may be about 5 mJ or more, about 10 mJ or more, or about 20 mJ or more.

In an embodiment, when the light-blocking composition is irradiated with ultraviolet rays of greater than about 100 mJ, yellowing occurs in the support film. When an excessive amount of ultraviolet rays (that is, ultraviolet rays of greater than about 100 mJ) is provided to the support film including an organic material, a photooxidation reaction causes yellowing of the support film. On the other hand, in the step of forming the preliminary light-blocking pattern P-BM (see FIG. 9), a total amount of the ultraviolet rays LT-1 provided to the light-blocking composition BC is about 100 mJ or less, and thus it is possible to prevent yellowing of the support film EOF.

In an embodiment and referring to FIG. 9, the preliminary light-blocking pattern P-BM may be formed on one surface EOF_DF of the support film EOF. Thereafter, coating liquid CAL may be provided on the other surface EOF_UF of the support film EOF, where the coating liquid CAL is provided to form a coating window CW (see FIG. 10) and may be provided directly on the other surface EOF_UF of the support film EOF. The coating window CW (see FIG. 10) may be formed by curing the coating liquid CAL provided on the other surface EOF_UF of the support film EOF. The coating liquid CAL may include an organic material. For example, the coating liquid CAL may include a base resin such as a silicone-based resin, a polyurethane-based resin, a urethane acrylate-based resin, a polyurea-based resin, or an epoxy-based resin. The base resin of the coating liquid CAL may include a thermosetting resin or a photocurable resin. For example, the coating liquid CAL may include a thermosetting resin. However, this is presented as an example, and a material included in the coating liquid CAL is not limited thereto.

In an embodiment, the coating window CW formed by providing the coating liquid CAL may have a pencil hardness of about 9H or more, a bright spot occurrence height of about 11 cm or more, as evaluated with a Dupont impact tester, and an indentation modulus (EIT) of about 800 MPa or more, as measured with a Nano indenter. FIG. 9 illustrates that the coating liquid CAL is provided through a nozzle NZ, but an apparatus for providing the coating liquid CAL is not limited thereto.

In an embodiment and referring to FIG. 10, a display module DM including a display panel DP and an input-sensing part TSP may be accommodated in a housing HAU, and the preliminary window member P-WP may be provided. Also, when the display module DM is accommodated in the housing HAU, other components of the electronic apparatus EA (see FIG. 3) (for example, the lower member CP, the protective film PF, the module adhesive layer AL2, the light control layer PP, the optical adhesive layer AL1, etc.) may be further accommodated in the housing HAU.

In an embodiment, the window member WP (see FIG. 3) including the light-blocking pattern BM (see FIG. 3) may be formed by irradiating, with near-infrared rays LT-2, a preliminary light-blocking pattern P-BM included in the preliminary window member P-WP. Due to irradiation with the near-infrared rays LT-2, the light-blocking pattern BM (see FIG. 3) and the housing HAU may be physically/chemically coupled. The step of irradiating with the near-infrared rays LT-2 may be a main curing step.

In an embodiment, the light-blocking pattern BM (see FIG. 3) formed through the irradiation with the ultraviolet rays LT-1 (see FIG. 8) and the near-infrared rays LT-2 may have an optical density of about 3 or more. Additionally, the light-blocking pattern BM (see FIG. 3) thus formed may have an adhesive force of about 5B or more with respect to the support film EOF and the housing HAU, and the adhesive force may be measured using the ASTM D3359 method.

In an embodiment, the step of forming the window member WP (see FIG. 3) through the irradiation with the near-infrared rays LT-2 may be performed at a temperature of about 80° C. or less. For example, the step of forming the window member WP (see FIG. 3) through the irradiation with the near-infrared rays LT-2 may be performed at a temperature of about 10° C. or more or about 20° C. or more.

In an embodiment, when the window member is formed at a temperature of greater than about 80° C., a high temperature (that is, a temperature of greater than about 80° C.) causes damage to the display panel, etc. On the other hand, in the electronic apparatus manufacturing method, the step of forming the window member WP (see FIG. 3) is performed at a temperature of about 80° C. or less, thereby achieving excellent processability.

In an embodiment, the near-infrared rays LT-2 may pass through the coating window CW and the support film EOF to be emitted to the preliminary light-blocking pattern P-BM. The coating window CW and the support film EOF may each have a transmittance of about 50% or more with respect to the near-infrared rays LT-2. The coating window CW and the support film EOF may each have a transmittance of about 50% or more with respect to light having a wavelength range of about 700 nm to about 1000 nm. Accordingly, the near-infrared rays LT-2 may pass through the coating window CW and the support film EOF and reach the preliminary light-blocking pattern P-BM. The near-infrared rays LT-2 do not react (for example, chemical reactions such as a photooxidation, etc.) with organic materials included in the coating window CW and the support film EOF.

Unlike the electronic apparatus manufacturing method, according to an embodiment, when the preliminary light-blocking pattern is irradiated with ultraviolet rays to form a light-blocking pattern, yellowing occurs in the coating window and the support film. Since the coating window and the support film include organic materials, yellowing occurs when irradiating with excessive amounts of ultraviolet rays. Additionally, since the coating window and the support film have properties of blocking ultraviolet rays in consideration of usage environments for users, the emitted ultraviolet rays do not pass through the coating window and the support film, or the emitted ultraviolet rays are unable to reach a lower side of the preliminary light-blocking pattern (that is, a deeper part in the thickness direction DR3). Accordingly, when the preliminary light-blocking pattern is irradiated with the ultraviolet rays, the light-blocking pattern is not formed from the preliminary light-blocking pattern.

In the electronic apparatus manufacturing method, according to an embodiment, the light-blocking pattern BM is formed through irradiation with the near-infrared rays LT-2, and thus damage (that is, yellowing) of the coating window CW and the support film EOF does not occur, and even the lower side of the preliminary light-blocking pattern P-BM may be easily cured. Also, the electronic apparatus manufacturing method, according to an embodiment, may not include a step of providing and curing an additional adhesive agent for coupling the window member WP (see FIG. 3) and the housing HAU. Therefore, the electronic apparatus manufacturing method, according to an embodiment, may exhibit excellent processability and excellent manufacturing efficiency.

In an embodiment, an electronic apparatus may include a window member disposed on a display panel. The window member may include a light-blocking pattern spaced apart from a coating window with a support film disposed therebetween. The light-blocking pattern may be formed of a light-blocking composition, and the light-blocking composition may include a black colorant, an ultraviolet photoinitiator, a near-infrared photoinitiator, a near-infrared photosensitizer, and an adhesive resin. Accordingly, the light-blocking pattern may couple the housing and the window member without an additional adhesive agent, and thus light leakage may be prevented. Therefore, the electronic apparatus, according to an embodiment, may exhibit excellent display quality, and may have a reduced thickness and an improved surface quality.

In an embodiment, an electronic apparatus may be manufactured through an electronic apparatus manufacturing method. The electronic apparatus manufacturing method may include a step of forming a preliminary light-blocking pattern by providing a light-blocking composition, and a step of forming a light-blocking pattern by irradiating the preliminary light-blocking pattern with near-infrared rays. Accordingly, the light-blocking pattern may be formed without damage of a coating window and a support film, and thus the electronic apparatus manufacturing method may exhibit excellent processability and excellent manufacturing efficiency.

In an embodiment, an electronic apparatus includes a light-blocking pattern disposed under a support film, and thus may have a reduced thickness and improved surface quality, and exhibit an excellent display quality.

In an embodiment, an electronic apparatus manufacturing method includes a step of forming a light-shielding pattern through irradiation with near-infrared rays, and may thus exhibit excellent processability and excellent manufacturing efficiency.

Although embodiments of the invention have been described, it is understood that the invention should not be limited to these embodiments but various changes and modifications can be made by one ordinary skilled in the art within the spirit and scope of the invention.

Therefore, the technical scope of the invention is not limited to the contents described in the detailed description of the specification, but should be determined by the claims. In addition, embodiments disclosed herein are not intended to limit the technical spirit of the invention, and all technical ideas disclosed herein should be construed as being included in the scope of the invention. Moreover, embodiments or parts of the embodiments may be combined in whole or in part without departing from the scope of the invention.

What is claimed is:

1. An electronic apparatus comprising:
a display panel; and
a window member disposed on the display panel, and including a support film, a coating window disposed on the support film, and a light-blocking pattern spaced apart from the coating window with the support film disposed therebetween,
wherein the light-blocking pattern is formed of a light-blocking composition including a black colorant, an ultraviolet photoinitiator, a near-infrared photosensitizer, a near-infrared photoinitiator, and an adhesive resin.

2. The electronic apparatus of claim 1, wherein a first edge of the coating window, a second edge of the support film, and a third edge of the light-blocking pattern are directed parallel to each other in a thickness direction.

3. The electronic apparatus of claim 1, further comprising:
a light control layer disposed between the display panel and the window member; and
an optical adhesive layer disposed between the light control layer and the window member,
wherein a side surface of the light-blocking pattern is in contact with the optical adhesive layer.

4. The electronic apparatus of claim 3, wherein the optical adhesive layer covers a stepped portion defined by the side surface of the light-blocking pattern and a lower surface of the support film.

5. The electronic apparatus of claim 3, wherein the optical adhesive layer has a thickness range of about 100 μm to about 200 μm.

6. The electronic apparatus of claim 1, wherein the light-blocking pattern has an optical density (OD) of about 3 or more, and an adhesive force of about 5B or more with respect to the support film, as measured in accordance with an ASTM D3359 method.

7. The electronic apparatus of claim 1, wherein the light-blocking pattern has a thickness range of about 3 μm to about 50 μm.

8. The electronic apparatus of claim 1, further comprising a housing in which the display panel is accommodated,
wherein an upper surface of the light-blocking pattern is in contact with the support film, and a lower surface of the light-blocking pattern is in contact with the housing.

9. The electronic apparatus of claim 1, wherein the support film entirely overlaps the coating window.

10. The electronic apparatus of claim 1, wherein the coating window has a pencil hardness of about 9H or more, a bright spot occurrence height of about 11 cm or more, as evaluated with a Dupont impact tester, and an indentation modulus (EIT) of about 800 MPa or more, as measured with a Nano indenter.

11. The electronic apparatus of claim 1, wherein the coating window has a transmittance of about 90% or more with respect to light having a visible light wavelength range, and a yellow index of about 1 or less.

12. The electronic apparatus of claim 1, wherein the support film and the coating window each have a transmittance of about 50% or more with respect to light having a wavelength range of about 700 nm to about 1000 nm.

13. The electronic apparatus of claim 1, wherein the coating window has a thickness range of about 300 μm to about 800 μm, and wherein the support film has a thickness range of about 100 μm to about 200 μm.

14. The electronic apparatus of claim 1, wherein the ultraviolet photoinitiator comprises an iodonium salt,
the near-infrared photosensitizer comprises a heptamethine cyanine dye,
the near-infrared photoinitiator comprises a coumarinacyl anilinium salt (CAA salt), and
the adhesive resin comprises at least one of a silicone-based resin, a urethane-based resin, or an acryl-based resin.

15. A method for manufacturing an electronic apparatus, the method comprising:
preparing a preliminary window member including a support film, a coating window disposed on the support film, and a preliminary light-blocking pattern spaced apart from the coating window with the support film disposed therebetween;
accommodating a display panel in a housing, and providing the preliminary window member on the display panel; and
forming a window member by irradiating the preliminary light-blocking pattern with near-infrared rays,
wherein the preparing of the preliminary window member includes
preparing the support film,
forming the preliminary light-blocking pattern by providing a light-blocking composition on one surface of the support film, and irradiating the light-blocking composition with ultraviolet rays; and
forming a coating window by providing a coating liquid on an other surface of the support film which is spaced apart from the one surface directed in a thickness direction,
wherein the light-blocking composition includes a black colorant, an ultraviolet photoinitiator, a near-infrared photosensitizer, a near-infrared photoinitiator, and an adhesive resin.

16. The method of claim 15, wherein in the forming of the window member, the near-infrared rays pass through the support film and the coating window to be irradiated to the preliminary light-blocking pattern.

17. The method of claim 15, wherein the forming of the window member is performed at a temperature of about 80° C. or less.

18. The method of claim 15, wherein in the forming of the preliminary light-blocking pattern, a total amount of the ultraviolet rays provided is about 100 mJ or less.

19. The method of claim 15, wherein the ultraviolet photoinitiator comprises an iodonium salt,
the near-infrared photosensitizer comprises a heptamethine cyanine dye,
the near-infrared photoinitiator comprises a coumarinacyl anilinium salt (CAA salt), and
the adhesive resin comprises at least one of a silicone-based resin, a urethane-based resin, or an acryl-based resin.

20. The method of claim 15, wherein the light-blocking composition is provided through an inkjet printing method or a dispensing method.
